(19) United States
(12) Patent Application Publication
(10) Pub. No.: US 2011/0108926 A1
(43) Pub. Date: May 12, 2011

(54) Gated anti-fuse in CMOS process

(75) Inventor: Sandeep R. Bahl, Palo Alto, CA (US)

(73) Assignee: National Semiconductor Corporation

(21) Appl. No.: 12/590,695

(22) Filed: Nov. 12, 2009

(51) Int. Cl. H01L 27/06

(52) U.S. Cl. 257/379; 257/E27.014

(57) ABSTRACT

In a gated anti-fuse, an anode is separated from a cathode by an oxide layer and the anode or cathode voltage is controlled by the control gate of a transistor like structure connected to the anode or cathode.

### FIELD OF THE INVENTION

The invention relates to one time programmable (OTP) memory devices. In particular it relates to OTPs implemented in a CMOS process.

### BACKGROUND OF THE INVENTION

In order to trim elements such as resistors and amplifiers in a circuit it is common to introduce programmable devices that can be selectively programmed. Embedded memory devices such as Electrically Erasable Programmable Read Only Memory (EEPROM) and one-time Erasable Programmable Read Only Memory (EPROM), also referred to as floating gate memories are commonly used for this purpose as well as for data retention. However, not only are EPROMs and EEPROMs rather costly, they also require a thick gate oxide for adequate reliability. In particular the reliability criteria for floating gate devices is measured by the duration of charge retention, and in the case of EEPROMs, also by the extent to which charge retention is maintained even after numerous program-erase cycles. Typically an EEPROM should be able to retain its readable charge for several years. In order to achieve this, a minimum gate oxide thickness of 60 Å for EPROM and 80 Å for EEPROM is typically required. Modern CMOS processes, typically provide for a lower oxide thickness and therefore don't readily lend themselves to the formation of integrated floating gate devices. Furthermore, floating gate devices are not radiation tolerant.

Another solution involves the use of OTP elements such as polysilicon fuses, metal Zener diode anti-fuses, silicon Zener diode anti-fuses, and laser trimmed metal fuses. These are, however, also associated with problems. The electrically programmable elements are associated with long programming times, high programming currents, poor reliability and debris in the form of particles when the gate is blown. The laser trimmed fuses, in turn, have the disadvantage that they cannot be programmed after packaging.

It is therefore desirable to have a one-time programmable element which does not require high currents, can be programmed relatively quickly with high yield and high reliability, does not pose debris problems, is radiation tolerant, and preferably lends itself to an array architecture. It is also desirable to be able to program the elements after packaging in order to take account of packaging related shifts. In addition the elements are preferably manufacturable in modern CMOS processes in which the oxide is too thin for floating gate memories.

### SUMMARY OF THE INVENTION

According to the invention, there is provided a gated anti-fuse, comprising an anti-fuse element and a gate-control element, wherein the anti-fuse element includes an anode separated by a first oxide layer from a cathode, and wherein the gate-control element defines a transistor that controls the voltage on one of the anode and cathode of the anti-fuse element. For purposes of this application the term “anode” is used to refer to the high voltage region and “cathode” to the low voltage region irrespective of whether the anode or cathode region is n-doped or p-doped.

The anti-fuse element may comprise a first polysilicon structure separated by an oxide layer from a first n-well or p-well. The first polysilicon structure may define the anode of the anti-fuse element, and the first n-well or p-well may define the cathode. Instead, the first polysilicon structure may define the cathode of the anti-fuse element, and the first n-well or p-well may define the anode. At least one first highly doped n+ region, or p+ region may be formed in the first n-well or p-well. A resistor may be provided between a contact to the first polysilicon region and one of the first highly doped n+ regions or p+ regions. In order to control the breakdown voltage of the first oxide layer between the anode and the cathode, a first lightly doped region (LDD) may be formed next to the at least one first highly doped n+ region or p+ region, the LDD being of same polarity as the n+ region or p+ region in the first n-well or p-well. The anti-fuse element may be defined by an NMOS configuration structure in which two n+ regions are formed in the first well with the first well defined as a p-well and the first polysilicon structure formed over a channel region between the two n+ regions. The anti-fuse element may instead be defined by two n+ regions formed in an n-type first well and the first polysilicon structure may be formed over a channel region between the two n+ regions. First lightly doped regions, which may be implemented as n-type regions may be formed next to each of the n+ regions. The anti-fuse element may instead be defined by two p+ regions formed in an n-type first well or a p-type first well and the first polysilicon structure formed over a channel region between the two p+ regions.

The gate control element may be implemented as a transistor-like structure that includes an n-type source formed in a p-well, an n-type drain, and a second polysilicon control gate separated from a channel region between the drain and source by a second oxide layer. The n-type drain of the gate control element may be defined by the cathode of the anti-fuse element, in which case the anode of the anti-fuse element will be defined by the first polysilicon region. The n-type source of the gate control element may comprise an n+ region formed in a p-well that may be spaced from the drain by a field expansion region that defines at least part of the channel region, the second polysilicon control gate extending across the field expansion region. The gate control element may instead be implemented as a transistor-like structure that includes a p-type source formed in an n-well, a p-type drain, and a second polysilicon control gate separated from a channel region between the drain and source by a second oxide layer. The p-type drain may be defined by the anode of the anti-fuse element, in which case the first polysilicon region of the anti-fuse element will define the cathode. The p-type source of the gate control element PMOS may comprise a p+ region formed in an n-well that may be spaced from the drain by a field expansion region that defines at least part of the channel region, the second polysilicon control gate extending across the field expansion region. If the anti-fuse element is implemented as an NMOS configuration structure with two n+ regions formed in a p-well, the p-well is typically isolated from a substrate by a surrounding n-well and a deep n-well formed underneath the p-well. In this case, the surrounding n-well may be connected to the p-well and may define an n-well for the drain of the gate control element. The surrounding n-well may be connected to the p-well by a silicided region formed on a highly doped region that extends from the p-well to the surrounding n-well. The at least one first highly doped n+ region may define the highly doped region on which the silicided region is formed.

In the case of a PMOS gate control element, the drain of the PMOS control-gate will be a p-well, in which case the drain may be connected directly to the antifuse p-well. The deep n-well may surround the entire p-well and may be connected to the n-well on the source-side of the PMOS control gate. This would define the standard “PMOS” embodiment, and allow negative bit and word lines.

The source of the gate control element may be spaced from the wells of the antifuse element by a field expansion region that defines at least part of the channel region, the second polysilicon control gate extending across the field expansion region

Either one or both of the well in which the source of the gate control element is formed and the first well of the anti-fuse element may be implemented to have a retrograde doping profile (light doping at the top and heavier doping at the bottom) A second lightly doped region (second LDD) my be formed next to the source of the gate control element, the second LDD being of the same doping type as the source. A halo implant may be provided next to the second LDD, of opposite doping type to the second LDD. Typically the second oxide layer is formed to be at least as thick or thicker than the first oxide layer.

For purposes of this application the term high voltage LDD will refer to an LDD without a halo implant, although in an alternative embodiment, a halo may also be provided for the sake of compatibility with standard CMOS processes.

The lightly doped regions are also referred to herein as lightly doped drain (LDD) regions even when they are on the source side of the gate control element transistor-like structure.

The n-type source of the gate control element may be connected to ground, while the polysilicon control gate may be connected to a control voltage, which may be defined by a positive word line. The first polysilicon region of the anti-fuse element, in this case may define an anode connected to a bit line. The voltage differential between the first polysilicon region anode and the cathode when the gate control element is not on, may be defined by a resistor provided between the anode and the cathode.

In the case of a p-type source for the gate control element, the source may be connected to ground, while the polysilicon control gate may be connected to a low control voltage, which may be defined by a negative word line. The first polysilicon region of the anti-fuse element, in this case may define a cathode connected to a negative bit line, e.g., −VDD.

In order to provide greater insulation along the edge of the polysilicon control gate where electric field lines are highest, and thereby to increase breakdown voltage, a shallow trench isolation region (STI) may be formed at the edge of the polysilicon control gate between the gate and the anti-fuse element.

### BRIEF DESCRIPTION OF THE DRAWINGS

FIG. 1 shows a cross section through one embodiment of the invention,

FIG. 2 shows a circuit diagram of a 4-element array using gated anti-fuses of the invention,

FIG. 3 shows bit-line current vs. cathode voltage curves, and

FIG. 4 shows a cross section through another embodiment of the invention.

### DETAILED DESCRIPTION OF THE INVENTION

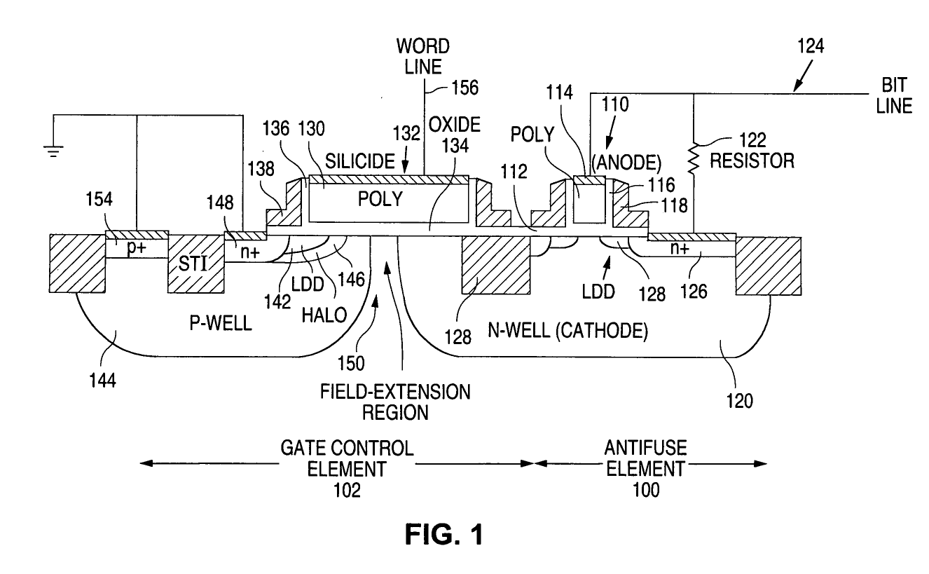

FIG. 1 shows one embodiment of a gated anti-fuse of the invention implemented in a CMOS process. The gated diode includes an anti-fuse element 100 and a gate control element 102. For ease of description the gate control element 102 will also be referred to herein as a transistor-like structure.

The anti-fuse element 100 includes an anode 110, which is implemented as a polysilicon region formed on an oxide layer 112, the polysilicon region also being referred to herein as the anti-fuse poly or first polysilicon region 110. Typically the polysilicon is silicided on its upper surface to provide a silicide contact 114. As will become clearer from the discussion below, while the anti-fuse poly in this embodiment defines an anode, it may in another embodiment define a cathode of the anti-fuse element, depending on the configuration of the gate control element. As shown in FIG. 1, the polysilicon 110 has an oxide layer 116 and a nitride spacer 118 on either side of it. The cathode (in this embodiment) of the anti-fuse element 100 is defined by an n-well 120 in this embodiment but it could be implemented in a p-well instead. In these figures, the back-end dielectrics and metallization are not shown, since they are typical of standard CMOS processes. In order to limit the voltage difference between the anode and the cathode when the anti-fuse element is not being programmed, as will be described in more detail below, a resistor 122 is provided between the anode and the cathode. In particular, in this embodiment, which is intended to be used in an array of gated anti-fuses, the anode is connected to a bit line 124. The resistor 122 extends between the anode, as depicted here by the connection to the bit line 124 and a silicided n+ region 126 formed in the n-well 120. The resistor 122 may be implemented using any available process resistors, e.g., an n+ unsilicided polysilicon having a resistance of about 100 kΩ was used in one embodiment, to provide a voltage difference between the anode and the cathode of less than 1V. In this embodiment, in order to increase the effective well doping under the poly anode 110 without the introduction of a counter-doping halo implant found in low-voltage lightly doped drain (LDD) implants, the n+ region 126 is formed with a high voltage lightly doped drain (LDD) implant 128 adjacent the region 126. The resultant higher effective doping under the poly anode 110 reduces the programming voltage by providing a smaller depletion region, and provides for a reduced on-resistance of the anti-fuse once the anti-fuse has been blown (programmed). This is particularly important if a retrograde doped n-well profile is used for the well 120 in which the n-well defining the cathode of the anti-fuse has a low doping concentration at the top. In other embodiments, standard CMOS wells and LDD implants with halos may also be substituted.

The gate control element 102 comprises a gated structure with a polysilicon gate 130 (also referred to herein as the second polysilicon region) having a silicided layer 132 on its upper surface, and formed on an oxide layer 134 that is equal to or thicker than the oxide layer 112. An oxide layer 136 and nitride spacer 138 is formed on either side of the gate 130, which will also be referred to herein as the control element poly. The gated structure 102 defines a transistor-like structure with a source, which in this embodiment takes the form of a silicided n+ region 148 formed in a p-well 144, and a drain that in this case defines the cathode of the anti-fuse element, as is discussed in greater detail below. The source in this embodiment includes a lightly doped region 142 formed by standard CMOS process, which for ease of reference will be referred to as a lightly doped drain (LDD) even though it is on the source side. The n+ region 140 and LDD 142 are formed in a p-well 144. A halo implant 146 of opposite polarity or doping type to that of the LDD 142 may also be introduced for threshold and leakage control. Both the LDD 142 and halo 146 are implemented by selectively opening a photoresist mask over the desired regions. The LDD and halo implant are formed by implanting impurities into the well along the edge of the polysilicon gate 130 next to the source. This is a standard procedure for forming LDDs and halo's, except that in standard CMOS processes, the resist is open over both source and drain regions, whereas in this embodiment, it is only open over the source and the adjacent portion of the gate. Typically the implant for the LDD is at a different angle e.g., 7 degrees compared to the halo implant which in this embodiment is implanted at 30 degrees. The purpose of the halo is to reduce the short channel effect on the control transistor side. As mentioned above, the p-well 144 may be implemented as a standard well or as a retrograde well. In one embodiment, the well 144 on the gate control element side was implemented as a retrograde well while a standard CMOS well was used for the anti-fuse.

It was found that poly lengths for the anti-fuse poly 110 between 0.1 u and 1 u yielded good results. In the embodiment of FIG. 1 an anti-fuse poly length of 0.4 u was used. In contrast the control element poly or gate poly 130 was chosen to lie in the range between 1 and 2 u and in this embodiment is 1.6 u. The poly width for the anti-fuse element is between 0.1 and 2 μm, with a typical value of 0.22 μm. The poly width for the control element poly is between 0.22 and 10 μm, with typical widths of 1-2 μm.

The drain side of the transistor-like gate control element in this embodiment defines the cathode of the anti-fuse element 100. As can be seen from FIG. 1, the p-well 144 in this embodiment is spaced from the n-well 120 by an optional field expansion region 150 in the channel below the gate 130. This allows the cathode to be biased to high voltages when the gate is off, as will become clearer from the discussion below. The field expansion region 150 and the thick oxide layer 134 are both high voltage features that enable high disturbance immunity from high voltages applied to the bit line. As seen in FIG. 1, the control element poly or polysilicon control gate 130 overlaps the n-well 120 (cathode of the anti-fuse element in this embodiment), terminating on a shallow trench isolation (STI) region 152, and in this embodiment, overlapping the STI 152. On the source side, the gate overlaps the p-well 144. In the present embodiment a retrograde doped profile is used for the n-well 120, however the wells 120, 144 may be implemented with a profile found in any standard CMOS process.

A p-well contact is provided for the gate control element by means of a silicided p+ region 154 formed in the p-well 144. In this embodiment the source voltage is defined by grounding the n+ source region 140. As shown, the p+ region 154 is also grounded. This configuration allows the anti-fuse to be used in a simple array consisting of positive word lines and bit lines. As shown in FIG. 1, a word line 156 is connected to the control element poly or gate 130 to control the voltage of the gate. As mentioned above, a bit line 124 is connected to the poly anode or anti-fuse poly 110. Thus the NMOS-like structure of the gate control element defines the n-well 120 as the cathode of the anti-fuse element by having its source connected to ground and thereby pulling the cathode of the anti-fuse element low when a positive voltage is applied to the second polysilicon gate 130.

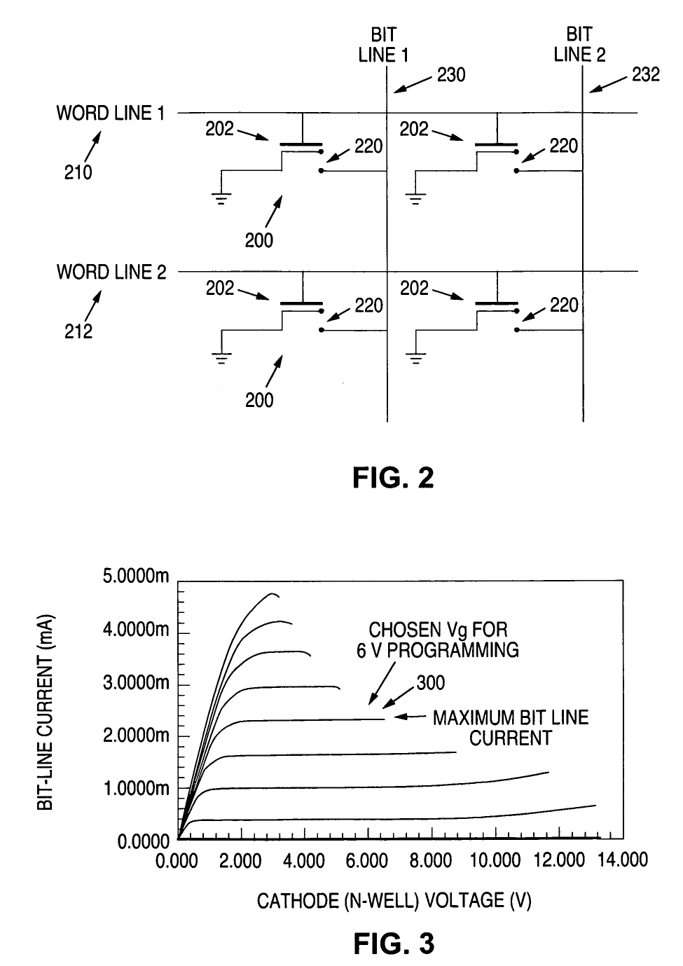

One embodiment of a simple array is shown in FIG. 2, which shows four gated anti-fuses 200 with their gates 202 (which define the control elements poly) connected to word lines 210, 212, and their anodes 220 (which define the anti-fuse poly) connected to bit lines 230, 232. It will be appreciated that the array is scaleable to larger sizes. In order to program an anti-fuse the bit line is held high (5 to 10V for an antifuse constructed in a 3V/1.2V dual gate oxide (DGO) CMOS process) while the word line is held at a medium voltage of 1 to 2 V. Initially, while the anti-fuse is in its unprogrammed state it is in a high resistance state due to the oxide layer between the anode and the cathode. Assuming cell (1,1) is to be programmed (the gated anti-fuse connected to word line 210 and bit line 230), the word line 210 would be held at 1-2V, turning on the transistor-like structure defined by the gate control element 102 in FIG. 1. This causes the cathode of the anti-fuse element 100 to be grounded. A high voltage pulse is then applied to the bit line 230 causing the anode to be at a high voltage and establishing a high potential difference across the oxide 112 between anode and cathode, sufficient to cause current flow through the oxide causing irreversible breakdown of the oxide and turning it into a low resistance state. Cells (2,1) and (2,2), which are both connected to word line 212 held at 0V are not affected since their gates are turned off. Thus when a program pulse is applied to bit line 230 the potential of the anti-fuse cathode rises due to current flow through the resistor 122 (FIG. 1). This prevents the potential difference across the oxide layer 112 that would otherwise program cell (2, 1). The thick oxide layer 134 under the gate and the field expansion region 150 provide good disturbance immunity of the cell by allowing it to withstand the high voltage programming pulse on its anode. It will be appreciated that cell (2,2) will also remain unprogrammed because in addition to its gate being held low, its anode is also low. In the case of cell (1,2) connected to word line 210 and bit line 232, even though the cathode is grounded by the word line, the programming pulse on bit line 232 is missing to program the cell.

In order to read a cell a medium voltage of 0.1-3 V is applied to the bit line and the word line is biased high (about 3V for a 3V/1.2V dual gate oxide (DGO) CMOS process) while the remaining lines are grounded. If the cell is unprogrammed the resistance across the anode-cathode will be dictated by resistor 122. On the other hand if the cell is programmed the oxide between anode and cathode will have broken down, thereby defining a low resistance current path between anode and cathode. Thus the state of the cell can readily be determined by the voltage drop across the anode and cathode. Since the gates of the other cells are off, they will prevent current flow through these other cells and thus will not affect the result.

The present invention makes use of a gate control element to provide current limiting after programming by controlling the voltage on the gate. As is discussed in greater detail below with respect to FIG. 3, this avoids high currents which could damage the drive and interconnect circuitry. In contrast, in prior art anti-fuses no current is initially passed until the fuse blows, whereafter there is a large current spike which may damage the drive and interconnect circuitry.

The bit line current vs. cathode voltage for the present embodiment is illustrated in FIG. 3 for a family of control gate voltages. First the drain voltage is chosen based on anti-fuse programming considerations. For a 20 Å anti-fuse oxide 112 (FIG. 1) this is a voltage of 5-7V. The gate voltage for the control gate 130 is then chosen to ensure that the gate control element remains within its safe operating range based on the resultant maximum current. The anti-fuse polysilicon area is then chosen such that the current density is high enough for successful programming at the above maximum current. An additional voltage margin can be incorporated by adding a resistor to the bit line. In the graphs of FIG. 3, we assume a programming voltage of 6V and a control gate voltage of 2V on word line 156. The control gate response of the structure of the present invention has the effect of limiting the bit line current as the cathode 120 is initially grounded by the word line turning on the gate control element 102. The antifuse element 100 blows due to the voltage across the anode-cathode oxide 112, causing the bit line current to rise (vertical axis) to approximately 2.3 mA as shown by the curve 300, at which point the control gate 102 limits the current flowing in the bit line.

In the embodiment of FIG. 1, the anti-fuse element 100 was implemented with its cathode defined by an n-well 120 with two n+ regions formed in the n-well. However, the present invention is not limited to this particular configuration.

For instance, the anti-fuse element could be implemented with the polarities reversed. In other words the well 120 could be implemented as a p-well and the n+ regions 112, 126 could be implemented as p+ regions. The LDD regions in such an embodiment would then also be of p-type. Instead the anti-fuse element could be implemented using a p+ region in an n-well. Instead the anti-fuse element can be implemented as an NMOS configuration structure with n+ regions formed in a p-well.

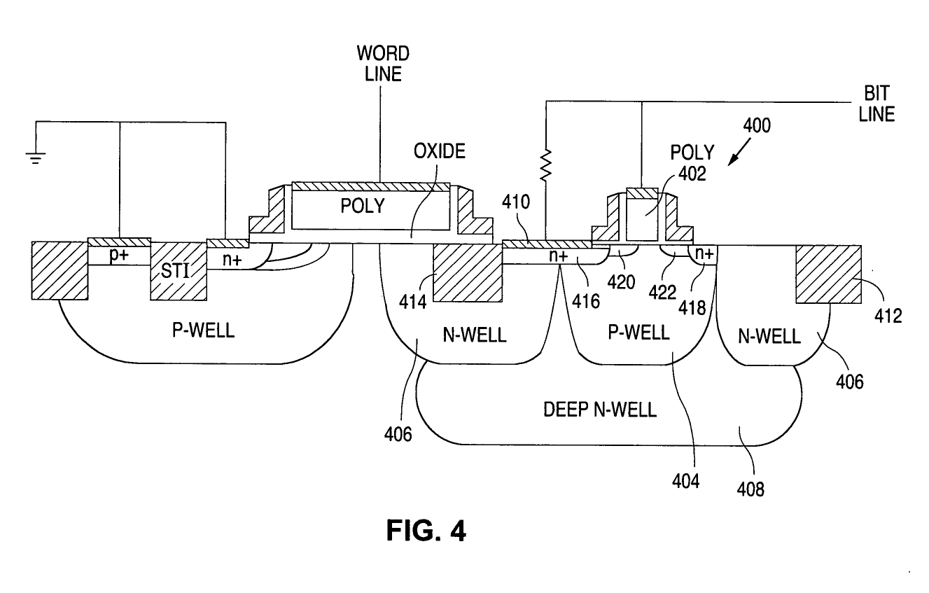

FIG. 4 shows an implementation of an embodiment where the anti-fuse element is implemented as an NMOS-like structure. The anti-fuse element 400 comprises an anti-fuse poly 402 forming the anode of the anti-fuse element, however in this embodiment the cathode is defined by a p-well 404. In order to isolate the p-well 404 from the substrate it is surrounded by an n-well 406 and a deep n-well 408 is formed below the p-well 404. Shallow trench isolation regions 412, 414 are formed on either side of the p-well 404 as shown. However, the p-well 404 is connected to the n-well 406 by means of a silicided region 410 formed on an n+ region 416 extending from the p-well 404 to the n-well 406. Thus, the anti-fuse element in this embodiment is defined by an NMOS configuration structure comprising the n+ region 416 and n+ region 418. Lightly doped regions 420, 422 of the same polarity to the n+ regions 416, 418 are formed next to the n+ regions. The gate control element in this embodiment is substantially the same as that for the embodiment of FIG. 1. In the embodiments of FIGS. 1 and 4 no halo implants of opposite polarity to the LDD regions, were introduced, however in other embodiments of the invention, the anti-fuse element may also include halo implants adjacent the LDD regions and of opposite doping type to the LDD regions.

It will therefore be appreciated that the present invention can be implemented in different ways without departing from the invention as defined by the claims.

For instance, the FIG. 4 embodiment could be implemented with a PMOS control-gate, the drain of the PMOS control-gate being defined by a p-well. The drain will then be connected directly to the antifuse p-well. In fact, it will be the same well. The deep-nwell will now surround this entire p-well and will be connected to the n-well on the source-side of the PMOS control gate. This would define the standard “PMOS” embodiment, and allow negative bit and word lines.

The anti-fuse structure of the present invention has the advantage that it does not need a bipolar supply since all operations can be done with a positive bit line and word line voltage for the NMOS-like version gate control transistor (having an n+ source and n-type drain as defined by the n-well 120) or with a negative voltage for the PMOS-like version of the gate control element having a p-type source and a p-type drain as defined by the well underneath the first polysilicon region of the anti-fuse element. In the present embodiment the gate oxide 134 is chosen to be thicker than the anode-cathode oxide 112 so that the gate-source voltage does not exceed the reliability limit of the gate oxide. However, in other embodiments the gate oxide 134 could be of the same thickness gate oxide 112. Also, as mentioned above, the programming voltage requirement is reduced by increasing the surface doping of the antifuse element by methods such as the use of a non-retrograde well, or in the case of the antifuse in the n-well, by introducing the high voltage LDD.

While the above embodiment dealt with fabrication in traditional silicon/silicon dioxide/polysilicon CMOS processes, the present invention is equally applicable to newer CMOS processes in which the gate is constructed of metal, the gate oxide contains a hafnium-based insulator, and the semiconductor contains germanium or carbon. For purposes of this application, the term oxide layer therefore includes a gate oxide that contains a hafnium-based insulator and any non-oxide insulators that may become available.

What is claimed is:

1. A gated anti-fuse, comprising
an anti-fuse element, and
a gate-control element, wherein the anti-fuse element includes an anode separated by a first oxide layer from a cathode, and wherein the gate-control element defines a transistor-like structure with a drain and a source, that controls the voltage on one of the anode and cathode of the anti-fuse element.

2. A gated anti-fuse of claim 1, wherein the anti-fuse element comprises a first polysilicon structure separated by an oxide layer from a first n-well or p-well.

3. A gated anti-fuse of claim 2, wherein the first polysilicon structure defines the anode of the anti-fuse element, and the first n-well or p-well defines the cathode.

4. A gated anti-fuse of claim 2, wherein the first polysilicon structure defines the cathode of the anti-fuse element, and the first n-well or p-well defines the anode.

5. A gated anti-fuse of claim 2, further comprising at least one first highly doped n+ region or p+ region formed in the first n-well or p-well, respectively.

6. A gated anti-fuse of claim 5, further comprising a resistor may be provided between a contact to the first polysilicon region and one of the first highly doped n+ regions or p+ regions.

7. A gated anti-fuse of claim 6, further comprising a first lightly doped region (LDD) formed next to at least one of the at least one first highly doped n+ region or p+ region, the LDD being of same polarity as said highly doped n+ region or p+ region.

8. A gated anti-fuse of claim 7, wherein the anti-fuse element is defined by an NMOS configuration structure in which two n+ regions are formed in the first well with the first well defined as a p-well and the first polysilicon structure formed over a channel region between the two n+ regions.

9. A gated anti-fuse of claim 7, wherein the anti-fuse element is defined by two n+ regions formed in an n-type first well and the first polysilicon structure is formed over a channel region between the two n+ regions.

10. A gated anti-fuse of claim 9, wherein first lightly doped n-type regions are formed next to each of the n+ regions.

11. A gated anti-fuse of claim 7, wherein the anti-fuse element is defined by two p+ regions formed in an n-type first well or a p-type first well and the first polysilicon structure is formed over a channel region between the two p+ regions.

12. A gated anti-fuse of claim 1, wherein the gate control element is implemented as a transistor-like structure that includes an n-type source formed in a p-well, an n-type drain, and a polysilicon control gate separated from a channel region between the drain and source by a second oxide layer.

13. A gated anti-fuse of claim 12, wherein the n-type drain of the gate control element is defined by the cathode of the anti-fuse element, and the anode of the anti-fuse element is defined by the first polysilicon region.

14. A gated anti-fuse of claim 13, wherein the n-type source of the gate control element comprises an n+ region formed in the p-well of the gate control element and is spaced from the drain by a field expansion region that defines at least part of the channel region, the second polysilicon control gate extending across the field expansion region.

15. A gated anti-fuse of claim 1, wherein the gate control element is implemented as a transistor-like structure that includes a p-type source formed in an n-well, a p-type drain, and a second polysilicon control gate separated from a channel region between the drain and source by a second oxide layer.

16. A gated anti-fuse of claim 15, wherein the p-type drain is defined by the anode of the anti-fuse element, in which case the first polysilicon region of the anti-fuse element defines the cathode of the anti-fuse element.

17. A gated anti-fuse of claim 16, wherein the p-type source of the gate control element comprises a p+ region formed in an n-well that is spaced from the drain by a field expansion region that defines at least part of the channel region, the second polysilicon control gate extending across the field expansion region.

18. A gated anti-fuse of claim 8, wherein the p-well of the anti-fuse element is isolated from a substrate by a surrounding n-well and a deep n-well formed underneath the p-well.

19. A gated anti-fuse of claim 18, wherein the surrounding n-well is connected to the p-well of the anti-fuse element and defines an n-well for the drain of the gate control element.

20. A gated anti-fuse of claim 19, wherein the surrounding n-well is connected to the p-well of the anti-fuse element by a silicided region formed on a highly doped region that extends from the p-well to the surrounding n-well.

21. A gated anti-fuse of claim 20, wherein the at least one first highly doped n+ region defines the highly doped region on which the silicided region is formed.

22. A gated anti-fuse of claim 2, wherein the gate control element is implemented as a transistor-like structure that includes an n-type source formed in a p-well, an n-type drain, and a second polysilicon control gate separated from a channel region between the drain and source by a second oxide layer.

23. A gated anti-fuse of claim 22, wherein either one or more of the well in which the source of the gate control element is formed and the first n-well or p-well of the anti-fuse element and any other wells defined by the anti-fuse element are implemented to have a retrograde doping profile (light doping at the top and heavier doping at the bottom).

24. A gated anti-fuse of claim 12, wherein a lightly doped region is formed next to the source of the gate control element, said lightly doped region being of the same doping type as the source.

25. A gated anti-fuse of claim 24, wherein a halo implant is provided next to the lightly doped region that is formed next to the source of the gate control element, the halo implant being of opposite doping type to said lightly doped region.

26. A gated anti-fuse of claim 12, wherein the second oxide layer is formed to be at least as thick or thicker than the first oxide layer.

27. A gated anti-fuse of claim 12, wherein a shallow trench isolation region (STI) is formed between the polysilicon control gate and the anti-fuse element.

28. A gated anti-fuse of claim 27, wherein the polysilicon control gate of the gate control element overlaps the STI.
